(19) United States
(12) Patent Application Publication
(10) Pub. No.: US 2008/0072949 A1
(43) Pub. Date: Mar. 27, 2008

(54) Solar energy charging system on windshield

(76) Inventors: Sandra L. Rowell, Cape Coral, FL (US); Gregory A. Rowell, Temperance, MI (US)

Correspondence Address: DENNIS G. LAPOINTE;LAPOINTE LAW GROUP, PL, PO BOX 1294, TARPON SPRINGS, FL, 34688-1294, US

(21) Appl. No.: 11/523,060

(22) Filed: Sep. 19, 2006

(51) Int. Cl. H02N 6/00; H01L 35/00; G08B 23/00

(52) U.S. Cl. 136/244; 136/206; 340/693.1

(57) ABSTRACT

A vehicular battery charging is accomplished by a solar battery charging system including a solar panel which can be attached to any edge of a windshield by way of being incorporated into the glass of the windshield or by being adhesively attached thereto. this system prevents the battery from being drained of its power when sitting in any location for a prolonged period of time.

### BACKGROUND OF THE INVENTION

Solar energy is a renewable energy source that is produced by the sun's rays. Solar energy sustains life on earth for all plants, animals and people. The earth receives radiant energy from the sun in the form of electromagnetic rays, which the sun continually emits into space. The energy takes the form as thermal photo voltaic that can be tapped as will be shown below.

It is a well known fact that when cars and other vessels are sitting for an extended period of time, this would drain the battery. The time it would take for the battery to drain would depend on the vehicle that is parked. The vehicle may have some electronic equipment operating, even though the engine is turned off, such as alarm systems or clocks. These equipments all will continue to consume electricity when the vehicle is parked with the engine off.

### BRIEF DESCRIPTION OF THE INVENTION

The system used to overcome the above noted problems is known as a “Battery Trickle Charger” which would keep batteries from draining while sitting for an extended length of time without going dead for cars, trucks, boats and all other products using any voltage chargers as solar panels. The system uses solar panels which may be installed on front or rear windshields which will keep the battery charged for a long period of time.

### BRIEF DESCRIPTION OF THE DRAWINGS

FIG. 1 illustrates a windshield having an upper solar panel installed thereon;

FIG. 2 is a perspective view of a corner of the windshield of FIG. 1;

FIG. 3 illustrates the windshield of FIG. 1 where the solar panel is installed on a lower edge of the wind shield;

FIG. 4 illustrates the overall system of a solar panel installation.

### DETAILED DESCRIPTION OF THE INVENTION

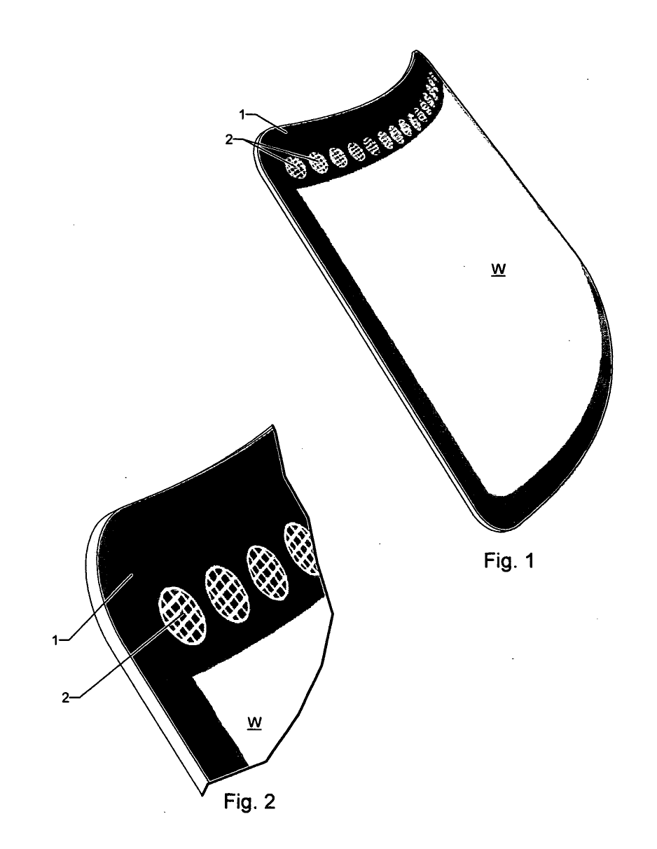

FIG. 1 illustrates a windshield W having a solar panel 1 installed on an upper edge of the windshield 1. The solar panel 1 has solar cells 2 incorporated within the solar panel itself. The solar panel 1 may be installed within the glass of the windshield. The solar cells are arranged in a series configuration. Windshields are known to be manufactured of two panes or layers of glass which are laminated together so that they are substantially shatter proof. This is a perfect process by which to incorporate the solar panel into the windshield to obtain a rigid unit of glass.

FIG. 2 illustrates the upper left hand corner of the windshield of FIG. 1 with the solar panel 1 incorporated therein. This view could also represent a rear windshield of a vehicle.

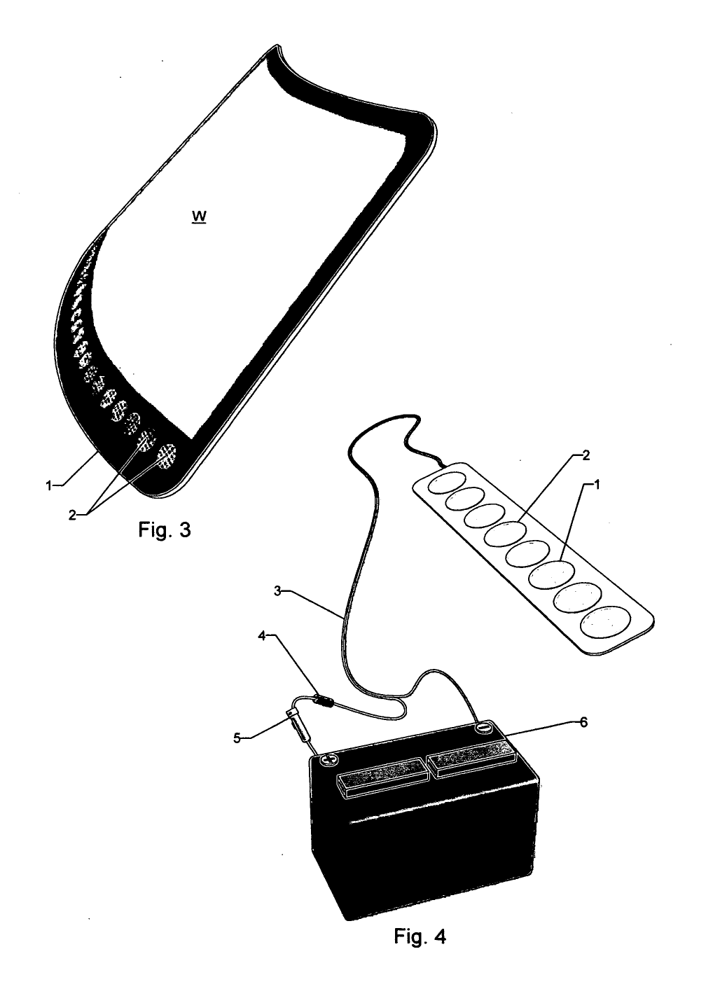

FIG. 3 shows that same view as shown in FIG. 1 but the solar panel 1 is installed at a lower edge of a windshield.

FIG. 4 shows the overall system of the Battery Trickle Charger. The solar panel 1 is shown by itself and this can well be so. In FIGS. 1-3 the solar panel 1 was shown to be incorporated into the windshield W. However, the solar panel 1 can be obtained as a retrofit into existing vehicles. The solar panel 1 may be adhesively fastened to an inside of a windshield, either at the top, the bottom, or on either side of the windshield with the same effects as if being incorporated into the glass. This lends itself well as a retrofit in existing vehicles, including boats. FIG. 4 further shows the electrical connections to be made between the solar panel and the battery of the vehicle. This view includes the wires 3 that lead from the solar panel to the battery 6. The positive lead of the wire 3 should include a diode which would prevent a feed back of the electricity flowing from the solar panel to the battery 6. The inclusion of a blocking diode prevents a solar panel from becoming a load on the battery and draining it at night when the sun has disappeared. The positive wire should be fused close to the battery. In the event of a wiring fault, fusing will prevent a dead short across the battery terminals and a possible fire.

The operating electrical values for Battery Trickle Chargers are suggested to be: 100 mA to 135 mA and 6V to 15V (2 W)

What we claim is:

1. A vehicle solar battery charging system comprising: a windshield, said windshield having at an edge thereof a solar panel attached thereto, said solar panel having solar cells therein, said solar cells are connected in a series configuration to each other and ultimately to a battery.

2. The solar battery charging system of claim 1, wherein said solar panel is part of said windshield.

3. The solar battery charging system of claim 1, wherein said solar panel is adhesively attached to said windshield.

4. The solar battery charging system of claim 1, wherein the electrical operating values of said system have a range of 100-135 aM and 6-12V at (2 W).
